(19) United States
(12) Patent Application Publication
(10) Pub. No.: US 2014/0354314 A1
(43) Pub. Date: Dec. 4, 2014

(54) THERMAL INTERFACE TECHNIQUES AND CONFIGURATIONS

(71) Applicants: Hitesh Arora, Chandler, AZ (US); Lawrence D. Decesare, JR., Chandler, AZ (US); Kelly P. Lofgreen, Phoenix, AZ (US); Andrew C. Lyman, Chandler, AZ (US); Michael A. Schroeder, Chandler, AZ (US)

(72) Inventors: Hitesh Arora, Chandler, AZ (US); Lawrence D. Decesare, JR., Chandler, AZ (US); Kelly P. Lofgreen, Phoenix, AZ (US); Andrew C. Lyman, Chandler, AZ (US); Michael A. Schroeder, Chandler, AZ (US)

(21) Appl. No.: 13/907,454

(22) Filed: May 31, 2013

(51) Int. Cl. G01R 31/28; B23P 15/26; F28F 3/12

(52) U.S. Cl. CPC G01R 31/2877; G01R 31/2896; F28F 3/12; B23P 15/26
USPC 324/750.09; 165/76; 29/890.03

(57) ABSTRACT

Embodiments of the present disclosure describe thermal interface techniques and configurations. In some embodiments, a thermal interface apparatus may include a flexible container, a plurality of thermally conductive objects disposed within the flexible container, and an attachment member coupled to the flexible container for attaching the thermal interface apparatus to a heat sink. The thermally conductive objects may be movable to rearrange their packing within the flexible container in response to deformation of the flexible container. Other embodiments may be described and/or claimed.

### FIELD

Embodiments of the present disclosure generally relate to the field of integrated circuits, and more particularly, to thermal interfaces.

### BACKGROUND

To dissipate potentially damaging heat during testing of integrated circuit (IC) packages, test fixtures may include a heat sink in thermal contact with IC components (such as dies). When the components of an IC package have differing heights, a thermal interface having springs or specially configured shapes are typically interposed between the IC package and the heat sink to achieve thermal contact with the components. Such thermal interfaces may be complex, expensive, difficult to reuse or adapt to different IC package designs, and limited in their thermal performance, which may inhibit the development of new IC package designs.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 is a cross-sectional side view of an example thermal interface apparatus, in accordance with some embodiments.

FIG. 2 is a cross-sectional side view of an example test fixture including the thermal interface apparatus of FIG. 1, in accordance with some embodiments.

FIGS. 3A-3E schematically illustrate various operations in the testing of an integrated circuit package using the test fixture of FIG. 2, in accordance with some embodiments.

FIG. 4 is a flow diagram of a method of providing thermal management during test of an integrated circuit package, in accordance with some embodiments.

FIGS. 5A-5C schematically illustrate embodiments of a thermal interface apparatus having thermally conductive objects of various nominal diameters, in accordance with some embodiments.

FIG. 6 is a flow diagram of a method of fabricating a thermal interface apparatus, in accordance with some embodiments.

FIG. 7 schematically illustrates a computing device that may include an integrated circuit package that may be thermally managed by a thermal interface apparatus, in accordance with some embodiments.

### DETAILED DESCRIPTION

Embodiments of the present disclosure describe thermal interface techniques and configurations. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

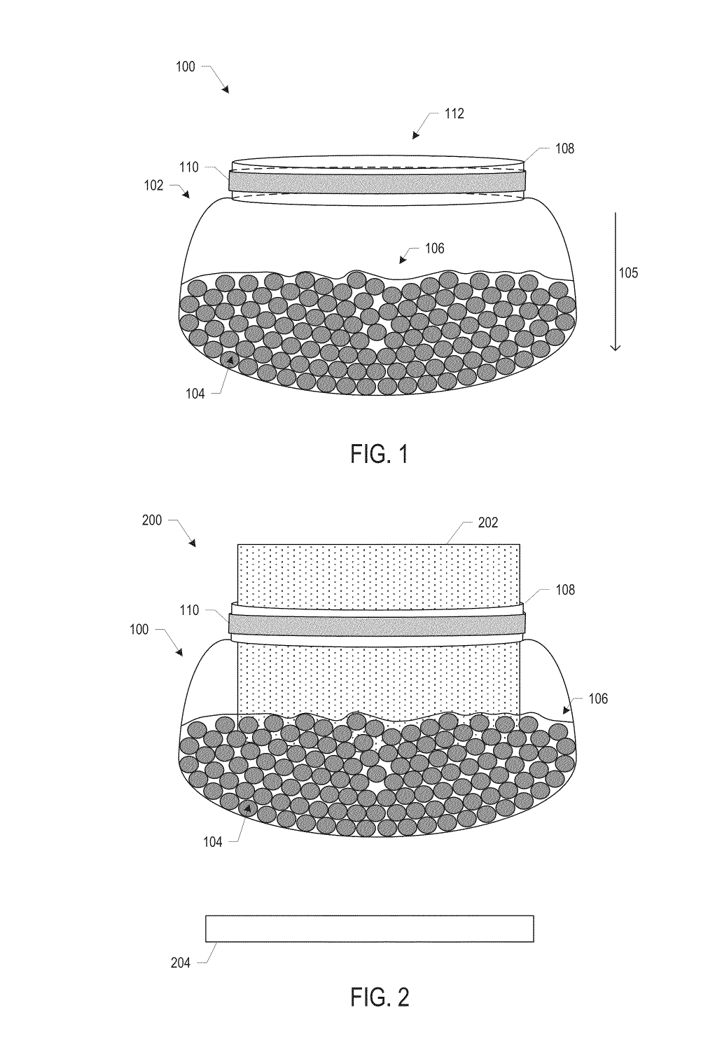

FIG. 1 is a cross-sectional side view of an example thermal interface apparatus (TIA) 100, in accordance with some embodiments. In general, the TIAs disclosed herein (such as the thermal interface apparatus 100) may include one or more materials with high thermal conductivity, such as copper, and may serve to conduct heat away from elements of an integrated circuit (IC) package or other device and toward a heat sink, heat spreader or other thermal management device. The heat sink or other device may spread this heat across a larger geometric area to increase the speed at which the heat radiates into the ambient environment, and/or may include one or more active cooling systems (e.g., one or more fans, or one or more liquid cooling systems). Though the TIAs disclosed herein will often be illustrated in an IC package test setting (wherein the thermal interface apparatus is arranged to conduct heat away from an IC package undergoing electrical or other performance testing), the TIAs disclosed herein may be used in any setting in which thermal interface materials are used or thermal management is desired. For example, the TIAs disclosed herein may be included in an end-user product instead of or in addition to traditional thermal interface materials, such as a thermal grease.

The TIA 100 may include a flexible container 102 and a plurality of thermally conductive objects (TCOs) 104 disposed within the flexible container 102. In some embodiments, the flexible container 102 may be fabricated from a material that allows the flexible container 102 to deform reversibly when mechanically perturbed such that the flexible container 102 substantially resumes its nominal shape once the perturbation is removed. In some embodiments, the flexible container 102 includes a metal film, a polymer film, or a filled polymer film. In some embodiments, the flexible container 102 may be formed from parafilm (having a thickness of, for example, less than 100 microns). In some embodiments, the flexible container 102 may be formed from a silicone film having a conductive filler. In some embodiments, the flexible container 102 may be formed from an aluminum film having a thickness between 20 microns and 50 microns (which may resist tearing or other damage when the flexible container 102 is deformed by contact with an IC package).

When formed from a film or other sheet material, the elasticity of the flexible container 102 may also be adjusted by selecting an appropriate thickness for the film. In some embodiments, the flexible container 102 is formed from a film having a thickness less than or equal to approximately 100 microns. The thermal conductivity of the flexible container 102 may also be adjusted to a desired value or range by the choice of materials forming the flexible container 102. In some embodiments, the thermal conductivity of the flexible container 102 may be in the range of 3-4 Watts/meter-Kelvin. In some embodiments, the thermal conductivity of the flexible container 102 may be greater than 4 Watts/meter-Kelvin.

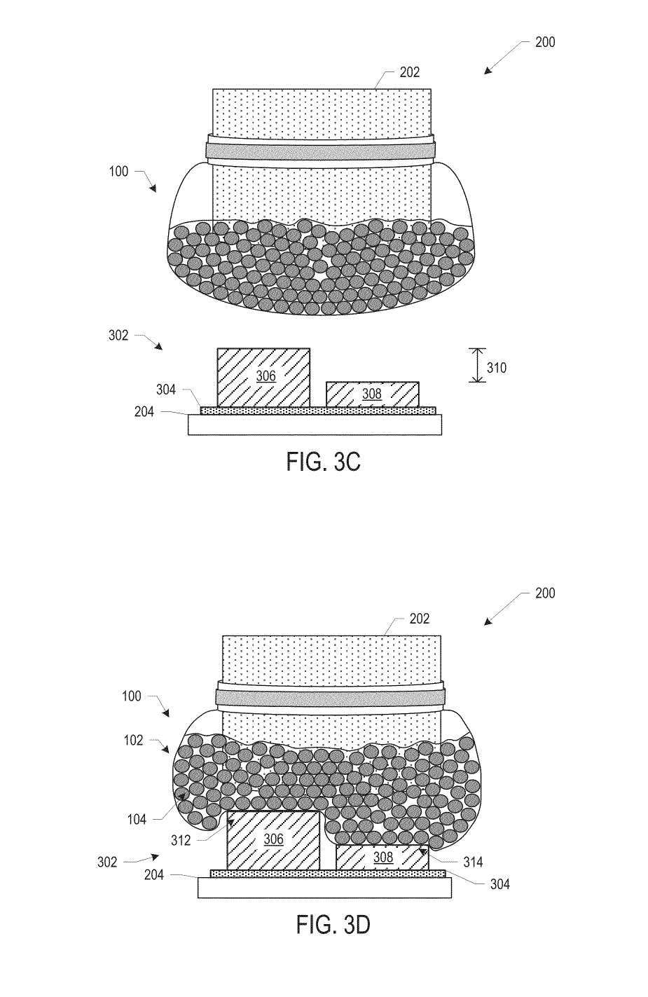

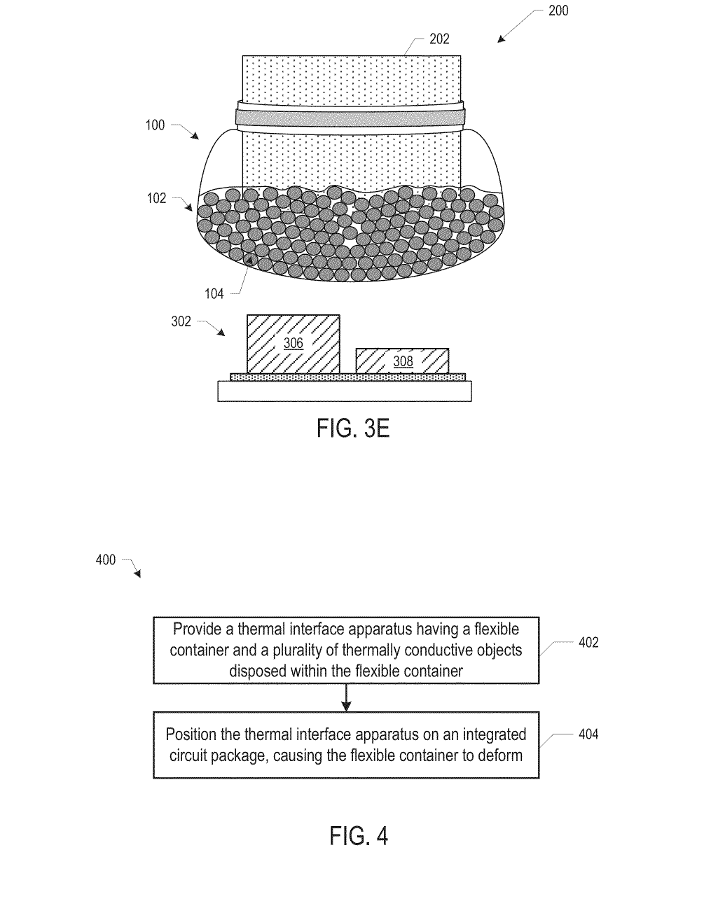

The TCOs 104, disposed within the flexible container 102, may be at least partially unconstrained within the flexible container 102. In some embodiments, the TCOs 104 may be movable to rearrange their packing within the flexible container 102 in response to deformation of the flexible container 102. In some embodiments, the force of gravity may act on the TCOs 104 to pull the TCOs 104 in the direction indicated by the arrow 105. When a mechanical force is applied to the flexible container 102 in a direction opposite to that indicated by the arrow 105, and deforms the flexible container 102, the TCOs 104 may rearrange their packing within the flexible container based on the action of each of the TCOs 104 due to the force of gravity and the applied force. In some embodiments, the TIA 100 may include a pressurization system (e.g., disposed within or adjacent to the flexible container 102) which may provide additional forces that may act on the TCOs 104 and the flexible container 102 in response to a deformation force and/or when the deformation force is removed (at which point the TIA 100 may substantially return to a non-deformed state). As discussed in detail below with reference to FIGS. 3A-3E and 4, the arrangement of the flexible container 102 and the TCOs 104 may allow the TIA 100 to deform when the TIA 100 is placed in contact with an IC package or other structure having components of different heights such that the flexible container 102 may deform to contact an upper surface of each the components and the TCOs 104 may rearrange to be positioned above each of the components, thereby achieving thermal contact between the TIA 100 and each of the components for effective thermal management.

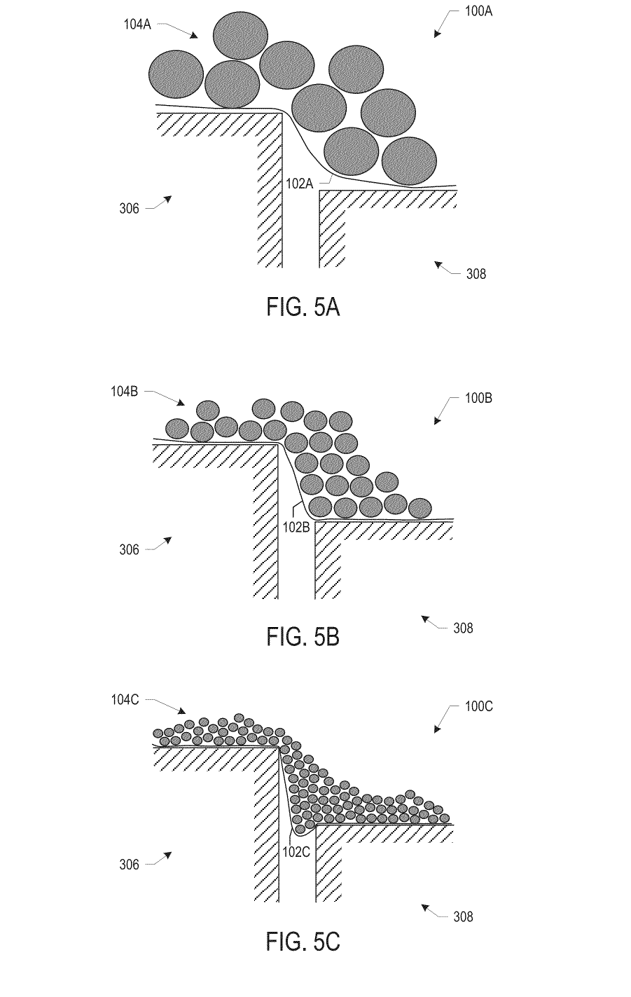

The TCOs 104 may be formed in any number of shapes, such as spheres or other round objects, cubes, cylinders, pyramids, cones, any other shape, or any combination of shapes. Different ones of the TCOs 104 may have different shapes. The TCOs 104 may be formed in any of a number of sizes, which may be characterized by a nominal diameter or other dimension. In some embodiments, the TCOs 104 may be roughly spherical with a nominal diameter of approximately 20 millimeters. Different ones of the TCOs 104 may have different sizes. In some embodiments, the nominal dimensions of the TCOs 104 may be selected based at least in part on one or more dimensions of an IC package to which the TIA 100 is intended to provide thermal management during testing. For example, in some embodiments, when the IC package has two adjacent components spaced a distance X apart, the nominal diameter of each of the TCOs 104 may be selected to be less than or equal to X/2. Embodiments of methods for selecting nominal dimensions for the TCOs 104 are discussed below with reference to FIGS. 4 and 5A-5C.

The thermal conductivity of the TCOs 104 may also be adjusted to a desired value or range by the choice of materials forming the TCOs 104. In some embodiments, the TCOs 104 may include solder balls. In some embodiments, the TCOs 104 include copper balls coated with gold or powders of highly thermally conductive metals (e.g., aluminum, tin, indium, tin-silver-copper alloy, etc.). In some embodiments, the TCOs 104 are formed from materials that provide the TCOs 104 with a thermal conductivity greater than approximately 100 Watts/meter-Kelvin. In some embodiments, a thermal conductivity of the TCOs 104 may be greater than a thermal conductivity of the flexible container 102. The choice of materials for the TCOs 104 may also be based on the tendency of the materials to oxidize, with low oxide formation preferable in test applications in which the TIA 100 may be repeatedly heated and cooled and exposed to oxygen in order to minimize the decline in thermal conductivity that may result from oxidation.

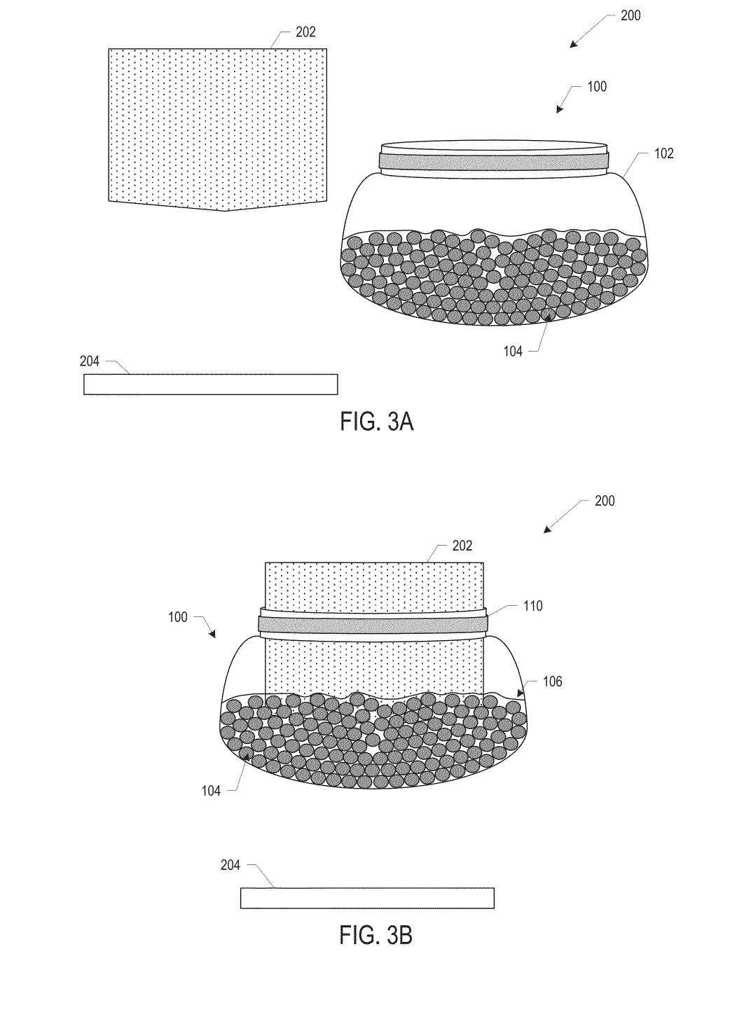

The TIA 100 may also include a thermally conductive fluid (TCF) 106 disposed within the flexible container 102. The TCF 106 may be mixed with the TCOs 104, and may improve heat transfer between the flexible container 102 and the TCOs 104 and/or between the TCOs 104 and a heat sink in thermal contact with the TCOs 104 (e.g., the heat sink 202, discussed below with reference to FIG. 2). In some embodiments, the TCF 106 may provide mechanical lubrication to the TIA 100 to reduce the friction between the TCOs 104 (and between the flexible container 102 and the TCOs 104) as the TCOs 104 rearrange in response to deformation of the flexible container 102. In some embodiments, the TCF 106 may include a silicone-metal grease (e.g., aluminum or zinc oxide greases), propanediol, silicon oil, water, or a combination of any suitable thermally conductive fluids. In some embodiments, a non-corrosive liquid may be selected for the TCF 106 (e.g., propanediol). In some embodiments, the thermal conductivity of the TCOs 104 may be greater than a thermal conductivity of the TCF 106. In some embodiments, no TCF may be disposed within the flexible container 102.

The TIA 100 may also include an attachment member 110, which may be coupled to a portion 108 of the flexible container 102 (e.g., using an adhesive, clamp, tie or any other construction). The attachment member 110 may be configured to couple the TIA 100 to another component, such as the heat sink 202 discussed below with reference to FIG. 2. As shown in FIG. 1, the flexible container 102 may include an opening 112; in some embodiments, the attachment member 110 may be disposed at one or more points around the opening 112, and may be configured to secure the TIA 100 to a component extending into the opening 112. In some embodiments, the attachment member 110 may include a clamp, a threaded connector, or a flexible tie. The attachment member 110 may include an O-ring. In some embodiments, the attachment member 110 may be disposed on the interior of the portion 108. In some embodiments, the attachment member 110 may include a permanent or temporary adhesive. In various embodiments, the attachment member 110 may be configured to permanently couple the TIA 100 to another component, or to removably couple the TIA 100 to another component. In some embodiments, the TIA 100 does not include an attachment member 110; instead, in embodiments in which the TIA 100 is to be coupled to another component, a separate attachment member or an attachment member integral to the other component may be used. For example, a component to which the TIA 100 is to be coupled may include one or more clips that are configured to secure the TIA 100 to the component.

FIG. 2 is a cross-sectional side view of an example test fixture 200 including the TIA 100 of FIG. 1, in accordance with some embodiments. The test fixture 200 may include a heat sink 202 and a platform 204. The heat sink 202 and the platform 204 may be coupled by an arm or other intermediate structure (not shown), such as a stand, to which the heat sink 202 and the platform 204 may be coupled. In some embodiments, the distance between the heat sink 202 and the platform 204 may be adjustable (for example, by manually adjusting clamps that secure the heat sink 202 and the platform 204 to a stand or by manually or automatically adjusting a screw drive).

In some embodiments, the test fixture 200 may be used to provide mechanical support, electrical connections, and/or thermal management to an IC package or other structure under test. In some such embodiments, the platform 204 may receive and support an IC package below the TIA 100. The heat sink 202 and the TIA 100 may then be moved closer to the platform 204 so that the TIA 100 makes thermal contact with the IC package. In some embodiments, the TIA 100 may be positioned to contact the IC package such that the flexible container 102 deforms in response to contact between the TIA 100 and the IC package. Examples of such embodiments are discussed below with reference to FIGS. 3A-3E. In some embodiments, the heat sink 202 remains in place while the platform 204 is moved, or both the heat sink 202 and the platform 204 are moved.

The heat sink 202 may be coupled to the TIA 100 by the attachment member 110, and may be in thermal contact with the TCOs 104 (and with the TCF 106, when included in the TIA 100). In some embodiments, the attachment member 110 may be removable from the heat sink 202. As shown in FIG. 2, in some embodiments, the heat sink 202 may extend into the flexible container 102 and make physical contact with the contents of the flexible container 102. As discussed above, the heat sink 202 may spread heat transferred from the TIA 100 across a larger geometric area to increase the speed at which the heat radiates into the ambient environment, and/or may include one or more active cooling systems (e.g., one or more fans, or one or more liquid cooling systems). In some embodiments, the heat sink 202 may include a passive cooling system, such as a metal block.

FIGS. 3A-3E schematically illustrate various operations in the testing of an IC package using the test fixture 200 of FIG. 2, in accordance with some embodiments. Referring to FIG. 3A, the test fixture 200 is illustrated having the TIA 100 separate from the heat sink 202 and the platform 204. As discussed above, the TIA 100 may include the flexible container 102 and a plurality of TCOs 104 disposed within the flexible container, such that the TCOs 104 are movable to rearrange their packing within the flexible container 102 in response to deformation of the flexible container 102.

Referring to FIG. 3B, the test fixture 200 is illustrated having the TIA 100 coupled to the heat sink 202. In some embodiments, the attachment member 110 is coupled to the flexible container 102 of the TIA 100, and the heat sink 202 is coupled to the attachment member 110. As discussed above, the attachment member 110 may include an O-ring, a clamp, adhesive, or any suitable mechanism for coupling the TIA 100 to the heat sink 202.

Referring to FIG. 3C, the test fixture 200 is illustrated as receiving an IC package 302 on the platform 204. The IC package 302 includes two components 306 and 308 mounted on a substrate 304. The components 306 and 308 may be electrically and/or mechanically coupled to the substrate 304 using solder bumps, copper pillars, or other conductive elements. In some embodiments, the components 306 and 308 may include one or more dies. For example, the component 306 may include a memory stack and the component 308 may be a central processing unit die. As shown, the component 306 is taller than the component 308 (as measured perpendicularly from the mounting surface of the substrate 304). The height difference between the component 306 and the component 308 (which may be referred to as the “stack up variation”) is indicated by the distance 310. In some embodiments, the distance 310 may be greater than or equal to 50 microns. In some embodiments, the distance 310 may be greater than or equal to 100 microns, greater than or equal to 150 microns, or greater than or equal to 200 microns. Only two components of the IC package 302 are shown for clarity of illustration; the IC package 302 may include more than two components, all or some of which may have different heights.

Referring to FIG. 3D, the test fixture 200 is illustrated having the TIA 100 positioned on the IC package 302. The contact between the IC package 302 and the TIA 100 may cause the flexible container 102 to deform to contact the upper surfaces 312 and 314 of the components 306 and 308, respectively. Further, some of the TCOs 104 may rearrange their packing so as to be positioned above the component 306 and some of the TCOs 104 may rearrange their packing so as to be positioned above the component 308. When positioned as shown in FIG. 3D, heat generated by the components 306 and 308 may be readily conducted away from the components 306 and 308 by the TIA 100 due to the good thermal contact between the TIA 100 and the components 306 and 308.

Referring to FIG. 3E, the test fixture 200 is illustrated having the TIA 100 spaced away from the IC package 302 after being in contact with the IC package 302 as shown in FIG. 3D. As discussed above, the flexible container 102 may be reversibly deformable, such that the flexible container returns to its pre-contact shape after the deformation illustrated in FIG. 3D. The TCOs 104 may rearrange themselves accordingly.

FIG. 4 is a flow diagram 400 of a method of providing thermal management during test of an IC package, in accordance with some embodiments. The method of flow diagram 400 may comport with actions described in connection with FIGS. 1, 2 and 3A-3E, in some embodiments. Various operations are described as multiple discrete operations in turn for illustrative purposes; the order of description should not be construed as to imply that these operations are necessarily order dependent.

At 402, a TIA may be provided. The TIA may include a flexible container and a plurality of TCOs disposed within the flexible container such that the TCOs are movable to rearrange their packing within the flexible container in response to deformation of the flexible container. In some embodiments, any of the TIAs discussed above (such as any of the embodiments of the TIA 100) may be provided at 402.

At 404, the TIA may be positioned on an IC package, causing the flexible container of the TIA to deform. In some embodiments, the IC package may have a first component and a second component, the first component taller than the second component, and the flexible container of the TIA may deform to contact an upper surface of each of the first and second components such that some of the TCOs rearrange their packing so as to be positioned above the first component and some of the TCOs rearrange their packing so as to be positioned above the second component. In some embodiments, the difference in height between the first and second components may be greater than or equal to 50 microns. In some embodiments, the difference in height between the first and second components may be greater than or equal to 100 microns.

Unlike traditional thermal greases, the TIA configurations and techniques disclosed herein may be used to provide thermal interfaces during testing or end-use that don't leave a sticky residue or other undesirable marking. This may allow effective thermal management during testing of parts that must be clean when sold or when incorporated into a larger device, thereby preventing thermal overload of sensitive electronics and excessive mechanical stress due to thermal variations. Such “large” heat spreaders may enable the use and development of large IC packages by providing advantageous thermal management not achievable using existing manufacturing technologies.

The thermal interface configurations and techniques disclosed herein may also be used repeatedly without losing elasticity (and thus the ability to readily conform to varying heights on the surface of test devices). Other thermal interfaces that may be used during test, such as spring- or foam-based interfaces, typically fail to provide sufficient flexibility and recovery ability, which drives up costs and slows down the test process. Spring-based systems may also suffer from unacceptably high failure rates. Additionally, embodiments of the TIA disclosed herein (e.g., the TIA 100 of FIG. 1) may be used sequentially on different shapes of IC packages and other devices, retaining the ability to conform to each, and need not be precisely positioned to provide good thermal performance; existing thermal interfaces may only be able to interface with a single shape, and must be precisely positioned for acceptable thermal contact.

As discussed above, various embodiments of the TIAs disclosed herein may include TCOs of various sizes (e.g., various nominal diameters). In some embodiments, including TCOs of smaller sizes may allow a TIA to more closely conform to the contours of the IC package or other structure with which the TIA comes into contact. FIGS. 5A-5C schematically illustrate embodiments of TIAs (TIAs 100A, 100B and 100C, respectively) having TCOs of various nominal diameters (TCOs 104A, 104B and 104C, respectively), in accordance with some embodiments. The TIAs 100A, 100B and 100C are shown as being in contact with IC package components 306 and 308, which have different heights.

As illustrated, the TCOs 104A of FIG. 5A have a larger nominal diameter than the TCOs 104B of FIG. 5B, and the TCOs 104B of FIG. 5B have a larger nominal diameter than the TCOs 104C of FIG. 5C. Including TCOs with smaller nominal diameters may allow the flexible container of the TIA (here, the flexible containers 102A, 102B and 102C, respectively) to more readily bend across the edge of a tall component to touch a shorter component, and therefore to more closely conform to the contours of the IC package (here, the components 306 and 308). In some embodiments, the distance between adjacent components of the IC package may be identified, and the nominal diameter of a TCO may be based at least in part on the identified distance. In an IC package with more than two components, or with non-rectangular components, a representative distance (such as the minimum distance between adjacent pairs of components, or an average distance) may be identified. In some embodiments, the nominal diameter of the TCOs included in a TIA may be selected to be less than the identified distance. In some embodiments, the nominal diameter of the TCOs included in a TIA may be selected to be less than one half of the identified distance. In some embodiments, the nominal diameter of the TCOs included in a TIA may be selected to be less than one quarter of the identified distance.

In some embodiments, a TIA may include TCOs of multiple sizes, shapes, and/or materials. For example, some TIAs may include TCOs of two different nominal diameters, which may improve the closeness of packing of the TCOs. The sizes, shapes, and/or materials selected for TCOs may be based on mechanical properties (e.g., weight or resistance to oxidation), thermal properties (e.g., to achieve a desired thermal conductivity), cost and/or availability, among others.

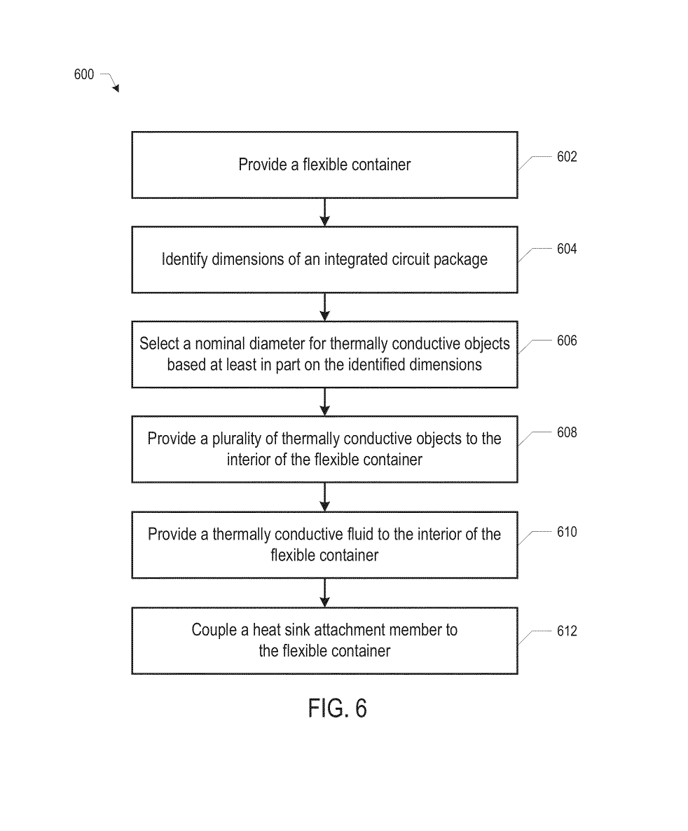

FIG. 6 is a flow diagram 600 of a method of fabricating a TIA (such as the TIA 100), in accordance with some embodiments. The method of flow diagram 600 may comport with actions described in connection with FIGS. 1, 2, 3A-3E, 4 and 5A-5C, in some embodiments. Various operations are described as multiple discrete operations in turn for illustrative purposes; the order of description should not be construed as to imply that these operations are necessarily order dependent.

At 602, a flexible container may be provided. The flexible container provided at 602 may include any of the flexible containers described herein, including embodiments of the flexible container 102.

At 604, one or more dimensions of an IC package may be identified. In some embodiments, a distance between adjacent components on an IC package may be identified 604. As discussed above with reference to FIGS. 5A-5C, a distance between components identified at 604 may be a representative distance (e.g., a minimum distance between two or more components). In some embodiments, a representative height of components of an IC package (e.g., a maximum height or an average height) or a representative height differential (e.g., the maximum difference in heights between two components) may be identified at 604.

At 606, a nominal diameter for TCOs to be included in the TIA may be selected based at least in part on the one or more dimensions identified at 604. In some embodiments, the nominal diameter selected at 606 may be smaller than the distance between adjacent components (as identified at 604). In some embodiments, the nominal diameter selected at 606 may be smaller than half the distance between adjacent components (as identified at 604).

At 608, a plurality of TCOs having the nominal diameter selected at 606 may be provided to the interior of the flexible container. The TCOs may be movable to rearrange their packing within the flexible container in response to deformation of the flexible container, as discussed above with reference to TIA 100. In some embodiments, the TCOs may include solder balls. In some embodiments, TCOs of two or more different sizes may be provided to the interior of the flexible container at 608. In some embodiments, the TCOs may have a predetermined nominal diameter, and one or more of 604 and 606 may not be performed.

At 610, a TCF may be provided to the interior of the flexible container. The TCF provided at 610 may include any of the TCFs disclosed herein, such as thermal grease. In some embodiments, 610 may not be performed. At 612, a attachment member (e.g., the attachment member 110) may be coupled to the flexible container.

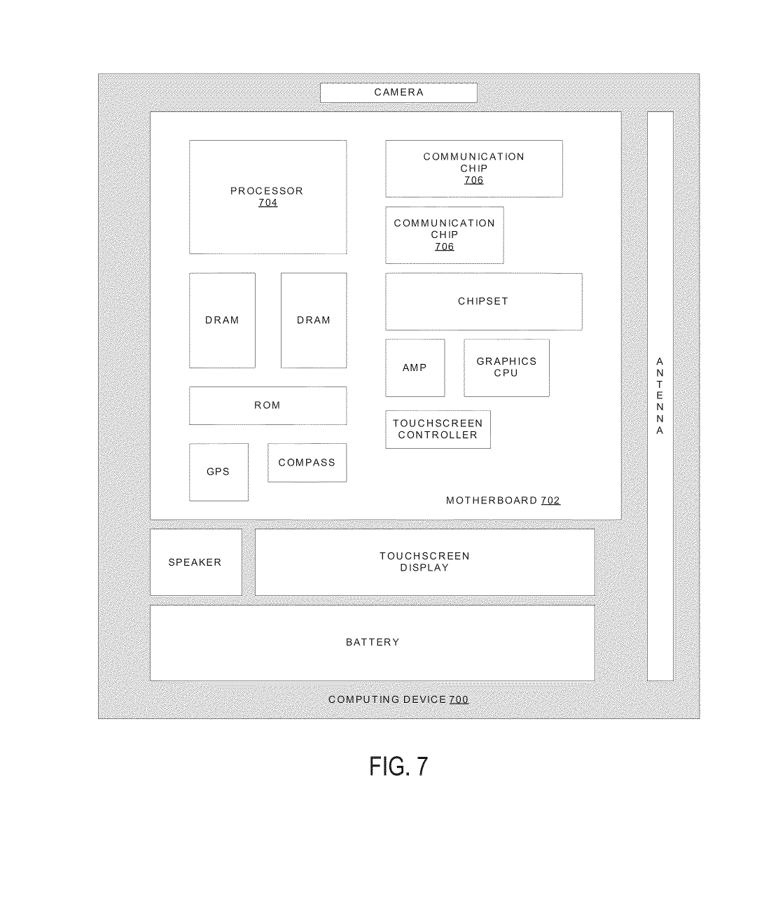

As discussed above with reference to FIG. 1, the TIAs disclosed herein may be used in any of a number of settings. For example, the TIAs disclosed herein may be put in thermal contact with an IC package during test of the IC package (as illustrated in FIGS. 3A-3E) or during end-use of the IC package (e.g., in the computing device 700 of FIG. 7, discussed below). The TIAs disclosed herein may be put in thermal contact with a heat spreader or other component spanning multiple IC packages; a TIA may be disposed between the heat spreader and the multiple IC packages, and/or between the heat spreader and a system-level heat sink or other thermal management device. In some embodiments, various properties of a TIA may be selected for the particular application, particularly when the available materials present a trade-off of different performance features. For example, in a test application, elasticity of the flexible container may be of primary importance (e.g., to ensure that the TIA will reversibly deform after each test) while the thermal conductivity of the flexible container may be less important; consequently, a material with lower thermal conductivity and higher elasticity may be selected for the flexible container. In an end-user application in which the TIA is not expected to be repeatedly deformed, elasticity of the flexible container may be less important, and thus a material with higher thermal conductivity and lower elasticity may be selected.

Embodiments of the present disclosure may be implemented into a system using any suitable hardware and/or software to configure as desired. FIG. 7 schematically illustrates a computing device 700 that may include an IC package that may be thermally managed by a TIA while under test or in the computing device 700, in accordance with some embodiments. In particular, any suitable one or more of the components of the computing device 700 may be thermally managed in accordance with the techniques disclosed herein, while under test and/or in the computing device 700.

The computing device 700 may house a board such as motherboard 702. The motherboard 702 may include a number of components, including but not limited to a processor 704 and at least one communication chip 706. The processor 704 may be physically and electrically coupled to the motherboard 702. In some implementations, the at least one communication chip 706 may also be physically and electrically coupled to the motherboard 702. In further implementations, the communication chip 706 may be part of the processor 704.

Depending on its applications, the computing device 700 may include other components that may or may not be physically and electrically coupled to the motherboard 702. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disc (CD), digital versatile disc (DVD), and so forth).

The communication chip 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 706 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 706 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 706 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 706 may operate in accordance with other wireless protocols in other embodiments.

The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 may include a die (e.g., included in the IC package 302 of FIG. 3C) as described herein. The term “processor” may refer to any device or portion of a device that processes electronic data from registers and/or memory to transform that electronic data into other electronic data that may be stored in registers and/or memory.

The communication chip 706 may also include a die (e.g., included in the IC package 302 of FIG. 3C) as described herein. In further implementations, another component (e.g., memory device or other integrated circuit device) housed within the computing device 700 may contain a die (e.g., included in the IC package 302 of FIG. 3C) as described herein. Such dies may be configured to send or receive signals through a bridge interconnect structure as described herein.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data. In some embodiments, the heat spreaders and IC packages described herein are implemented in a high-performance computing device. In some embodiments, the heat spreaders and IC packages described herein are implemented in handheld computing devices.

The above description of illustrated implementations, including what is described in the Abstract, is not intended to be exhaustive or to limit the disclosure to the precise forms disclosed. While specific implementations are described herein for illustrative purposes, various equivalent modifications are possible within the scope of the disclosure, as those skilled in the relevant art will recognize.

These modifications may be made to the disclosed embodiments in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The following paragraphs provide a number of examples of embodiments of the present disclosure.

Example 1A is a thermal interface apparatus, including a flexible container; a plurality of thermally conductive objects disposed within the flexible container such that the thermally conductive objects are movable to rearrange their packing within the flexible container in response to deformation of the flexible container; and an attachment member coupled to the flexible container for attaching the thermal interface apparatus to a heat sink.

Example 1B is the thermal interface apparatus of Example 1A, and further specifies that the flexible container deforms reversibly.

Example 1C is the thermal interface apparatus of any of Examples 1A-1B, and further specifies that the flexible container includes a metal film, a polymer film, or a filled polymer film.

Example 1D is the thermal interface apparatus of any of Examples 1A-1C, and further specifies that the flexible container includes a film having a thickness less than or equal to approximately 100 microns.

Example 1E is the thermal interface apparatus of Example 1A, and further specifies that the flexible container includes a metal film, a polymer film, or a filled polymer film, or wherein the flexible container includes a film having a thickness less than or equal to approximately 100 microns.

Example 1F is the thermal interface apparatus of any of any of Examples 1A-1E, and further specifies that the thermally conductive objects have a thermal conductivity greater than approximately 100 Watts/meter-Kelvin.

Example 1G is the thermal interface apparatus of any of any of Examples 1A-1F, and further specifies that, when the thermal interface apparatus is positioned on an integrated circuit package having a first component and a second component, the second component greater than or equal to 50 microns taller than the second component, the flexible container is configured to deform to contact an upper surface of each of the first and second components, some of the thermally conductive objects are movable to rearrange their packing so as to be positioned above the first component, and some of the thermally conductive objects are movable to rearrange their packing so as to be positioned above the second component.

Example 1H is the thermal interface apparatus of any of any of Examples 1A-1G, further including a thermally conductive fluid disposed within the flexible container and mixed with the thermally conductive objects.

Example 1I is the thermal interface apparatus of Example 1H, and further specifies that the thermally conductive fluid includes a silicone-metal grease or propanediol.

Example 1J is the thermal interface apparatus of Example 1H, and further specifies that the thermally conductive fluid includes a silicone-metal grease or propanediol, or wherein a thermal conductivity of the plurality of thermally conductive objects is greater than a thermal conductivity of the thermally conductive fluid, or wherein a thermal conductivity of the flexible container is less than a thermal conductivity of the plurality of thermally conductive objects.

Example 1K is the thermal interface apparatus of Example 1H, and further specifies that a thermal conductivity of the plurality of thermally conductive objects is greater than a thermal conductivity of the thermally conductive fluid.

Example 2A is a method of forming a thermal interface apparatus, including: providing a flexible container, the flexible container having an interior; providing a plurality of thermally conductive objects to the interior of the flexible container, the thermally conductive objects movable to rearrange their packing within the flexible container in response to deformation of the flexible container; and providing an attachment member for coupling to the flexible container for attaching the thermal interface apparatus to a heat sink.

Example 2B is the method of Example 2A, further including: prior to providing a plurality of thermally conductive objects to the interior of the flexible container, identifying a distance between adjacent components on an integrated circuit package, and selecting a nominal diameter for the thermally conductive objects based at least in part on the identified distance; wherein providing the plurality of thermally conductive objects to the interior of the flexible container includes providing a plurality of thermally conductive objects having the selected nominal diameter.

Example 2C is the method of Example 2B, and further specifies that selecting a nominal diameter of each of the thermally conductive objects based at least in part on the identified distance includes selecting a nominal diameter smaller than the identified distance.

Example 2D is the method of any of Examples 2A-2C, further including providing a thermally conductive fluid to the interior of the flexible container.

Example 2E is the method of any of Examples 2A-2D, and further specifies that the attachment member includes a clamp, a threaded connector, or an adhesive.

Example 2F is the method of any of Examples 2A-2E, and further specifies that the thermally conductive objects include solder balls.

Example 3A is a method of providing thermal management during test of an integrated circuit package, comprising: providing a thermal interface apparatus comprising a flexible container and a plurality of thermally conductive objects disposed within the flexible container such that the thermally conductive objects are movable to rearrange their packing within the flexible container in response to deformation of the flexible container; and positioning the thermal interface apparatus on an integrated circuit package having a first component and a second component, the first component taller than the second component, causing the flexible container to deform to contact an upper surface of each of the first and second components such that some of the thermally conductive objects rearrange their packing so as to be positioned above the first component and some of the thermally conductive objects rearrange their packing so as to be positioned above the second component.

Example 3B is the method of Example 3A, and further specifies that the first component is taller than the second component by an amount greater than or equal to 50 microns.

Example 4A is a method of providing a thermal interface apparatus, including forming a thermal interface apparatus by: providing a flexible container, the flexible container having an interior; providing a plurality of thermally conductive objects to the interior of the flexible container, the thermally conductive objects movable to rearrange their packing within the flexible container in response to deformation of the flexible container; and providing an attachment member for coupling to the flexible container for attaching the thermal interface apparatus to a heat sink.

Example 4B is the method of Example 4A, further including: prior to providing a plurality of thermally conductive objects to the interior of the flexible container, identifying a distance between adjacent components on an integrated circuit package, and selecting a nominal diameter for the thermally conductive objects based at least in part on the identified distance; wherein providing the plurality of thermally conductive objects to the interior of the flexible container includes providing a plurality of thermally conductive objects having the selected nominal diameter.

Example 4C is the method of Example 4B, wherein selecting a nominal diameter of each of the thermally conductive objects based at least in part on the identified distance includes selecting a nominal diameter smaller than the identified distance.

Example 4D is the method of any of Examples 4A-4C, wherein the attachment member includes a clamp, a threaded connector, or an adhesive, or wherein the thermally conductive objects include solder balls.

Example 4E is the method of any of Examples 4A-4D, further including: positioning the thermal interface apparatus on an integrated circuit package having a first component and a second component, the first component taller than the second component, causing the flexible container to deform to contact an upper surface of each of the first and second components such that some of the thermally conductive objects rearrange their packing so as to be positioned above the first component and some of the thermally conductive objects rearrange their packing so as to be positioned above the second component.

Example 5A is a test fixture, including: a heat sink; an attachment member coupled to the heat sink; and a thermal interface apparatus including a flexible container and a plurality of thermally conductive objects disposed within the flexible container such that the thermally conductive objects are movable to rearrange their packing within the flexible container in response to deformation of the flexible container, wherein the flexible container is coupled to the attachment member.

Example 5B is the test fixture of Example 5A, and further specifies that the attachment member is removable from the heat sink.

Example 5C is the test fixture of any of Examples 5A-5B, and further specifies that the heat sink includes a metal block.

Example 5D is the test fixture of any of Examples 5A-5C, and further specifies that the heat sink includes an active cooling system.

Example 5E is the test fixture of any of Examples 5A-5B, and further specifies that the heat sink includes a metal block or an active cooling system.

Example 5F is the test fixture of any of Examples 5A-5E, and further specifies that a thermal conductivity of the flexible container is less than a thermal conductivity of the thermally conductive objects.

Example 5G is the test fixture of any of Examples 5A-5F, further including a platform for receiving an integrated circuit package below the thermal interface apparatus.

Example 5H is the test fixture of Example 5F, wherein the thermal interface apparatus is positioned to contact the integrated circuit package such that the flexible container deforms in response to the contact.

Example 5I is the test fixture of Example 5F, and further specifies that the integrated circuit package has two adjacent components spaced a distance apart, and a ratio between a nominal diameter of each of the thermally conductive objects and the distance is less than or equal to 0.5.

What is claimed is:

1. A thermal interface apparatus, comprising:
a flexible container;
a plurality of thermally conductive objects disposed within the flexible container such that the thermally conductive objects are movable to rearrange their packing within the flexible container in response to deformation of the flexible container; and
an attachment member coupled to the flexible container for attaching the thermal interface apparatus to a heat sink.

2. The thermal interface apparatus of claim 1, wherein the flexible container deforms reversibly.

3. The thermal interface apparatus of claim 1, wherein the flexible container comprises a metal film, a polymer film, or a filled polymer film.

4. The thermal interface apparatus of claim 1, wherein the flexible container comprises a film having a thickness less than or equal to approximately 100 microns.

5. The thermal interface apparatus of claim 1, wherein the thermally conductive objects have a thermal conductivity greater than approximately 100 Watts/meter-Kelvin.

6. The thermal interface apparatus of claim 1, wherein, when the thermal interface apparatus is positioned on an integrated circuit package having a first component and a second component, the second component greater than or equal to 50 microns taller than the second component, the flexible container is configured to deform to contact an upper surface of each of the first and second components, some of the thermally conductive objects are movable to rearrange their packing so as to be positioned above the first component, and some of the thermally conductive objects are movable to rearrange their packing so as to be positioned above the second component.

7. The thermal interface apparatus of claim 1, further comprising:
a thermally conductive fluid disposed within the flexible container and mixed with the thermally conductive objects.

8. The thermal interface apparatus of claim 7, wherein the thermally conductive fluid comprises a silicone-metal grease or propanediol.

9. The thermal interface apparatus of claim 7, wherein a thermal conductivity of the plurality of thermally conductive objects is greater than a thermal conductivity of the thermally conductive fluid.

10. A method of forming a thermal interface apparatus, comprising:
providing a flexible container, the flexible container having an interior;
providing a plurality of thermally conductive objects to the interior of the flexible container, the thermally conductive objects movable to rearrange their packing within the flexible container in response to deformation of the flexible container; and
providing an attachment member for coupling to the flexible container for attaching the thermal interface apparatus to a heat sink.

11. The method of claim 10, further comprising:
prior to providing a plurality of thermally conductive objects to the interior of the flexible container,
identifying a distance between adjacent components on an integrated circuit package, and
selecting a nominal diameter for the thermally conductive objects based at least in part on the identified distance;
wherein providing the plurality of thermally conductive objects to the interior of the flexible container comprises providing a plurality of thermally conductive objects having the selected nominal diameter.

12. The method of claim 11, wherein selecting a nominal diameter of each of the thermally conductive objects based at least in part on the identified distance comprises selecting a nominal diameter smaller than the identified distance.

13. The method of claim 10, further comprising:
providing a thermally conductive fluid to the interior of the flexible container.

14. The method of claim 10, wherein the attachment member comprises a clamp, a threaded connector, or an adhesive.

15. The method of claim 10, wherein the thermally conductive objects comprise solder balls.

16. A test fixture, comprising:
a heat sink;
an attachment member coupled to the heat sink; and
a thermal interface apparatus comprising a flexible container and a plurality of thermally conductive objects disposed within the flexible container such that the thermally conductive objects are movable to rearrange their packing within the flexible container in response to deformation of the flexible container, wherein the flexible container is coupled to the attachment member.

17. The test fixture of claim 16, wherein the attachment member is removable from the heat sink.

18. The test fixture of claim 16, wherein the heat sink comprises a metal block.

19. The test fixture of claim 16, wherein the heat sink comprises an active cooling system.

20. The test fixture of claim 16, wherein a thermal conductivity of the flexible container is less than a thermal conductivity of the thermally conductive objects.

21. The test fixture of claim 16, further comprising a platform for receiving an integrated circuit package below the thermal interface apparatus.

22. The test fixture of claim 21, wherein the thermal interface apparatus is positioned to contact the integrated circuit package such that the flexible container deforms in response to the contact.

23. The test fixture of claim 21, wherein the integrated circuit package has two adjacent components spaced a distance apart, and a ratio between a nominal diameter of each of the thermally conductive objects and the distance is less than or equal to 0.5.

24. A method of providing thermal management during test of an integrated circuit package, comprising:
providing a thermal interface apparatus comprising a flexible container and a plurality of thermally conductive objects disposed within the flexible container such that the thermally conductive objects are movable to rearrange their packing within the flexible container in response to deformation of the flexible container; and
positioning the thermal interface apparatus on an integrated circuit package having a first component and a second component, the first component taller than the second component, causing the flexible container to deform to contact an upper surface of each of the first and second components such that some of the thermally conductive objects rearrange their packing so as to be positioned above the first component and some of the thermally conductive objects rearrange their packing so as to be positioned above the second component.

25. The method of claim 24, wherein the first component is taller than the second component by an amount greater than or equal to 50 microns.
